(19) United States
(12) Patent Application Publication
(10) Pub. No.: US 2001/0007371 A1
(43) Pub. Date: Jul. 12, 2001

(54) IC package and method of making the same

(75) Inventor: Masahiro Kawaguchi, Miyagi-ken (JP)

Correspondence Address: Motorola, Inc., Intellectual Property Department, Suite R3163, P.O. Box 10219, Scottsdale, AZ, 85271-0219, US

(73) Assignee: Motorola, Inc.

(21) Appl. No.: 09/753,835

(22) Filed: Jan. 3, 2001

(30) Foreign Application Priority Data
Jan. 6, 2000 (JP) 2000-000810

(51) Int. Cl. H01L 23/04

(52) U.S. Cl. 257/698

(57) ABSTRACT

An exposed I/O terminal is disposed on a side of an IC package according to the present invention. This IC package includes an IC chip mounting substrate, an IC chip mounted on the IC chip mounting substrate, and an encapsulating member for encapsulating the IC chip. On a side of the chip mounting substrate is formed a trench for exposing the conductor that forms at least a portion of the I/O terminal, and one end of this trench is closed by a cap member, and the encapsulating member covers the IC chip and cap member. Ceramic material may be used as a material for the chip mounting substrate and cap member. Alternatively, the chip mounting substrate may be comprised of a printed wiring board, while the cap member may be formed of a solder resist film.

### FIELD OF THE INVENTION

The present invention relates, in general, to semiconductor IC packages and fabrication methods therefore, and, in particular, to chip scale packages (CSP) for improving throughput and fabrication methods therefore.

### BACKGROUND OF THE INVENTION

FIG. 1 shows a cross-sectional view of a conventional chip scale package (100). The chip scale package (100) includes an interposer substrate (112), an IC chip (114) mounted on the interposer substrate (112), and an encapsulating resin (116) for covering the IC chip. The IC chip (114) is connected to wiring pattern on the interposer substrate (112) via wires (118), while the wiring pattern is connected to input/output (I/O) terminals (124) via a conductor (122) in a through hole (120). The “interposer substrate” is an insulating member located between the I/O terminal and IC chip of the IC package, and serves to define locations of I/O terminals. The IC package of this type does not require to cover (encapsulation) the entire IC package with resin, so it can facilitate miniaturization as compared to that of entire resin encapsulation. In other words, with the IC package of this type, the percentage occupied by the IC chip relative to the entire IC package is greater than that of the entire resin encapsulation. In view of enhanced functionality and improved performance in addition to miniaturization, it is desirable to maximize the percentage occupied by the IC chip as far as possible.

However, as the insulating member is made smaller, problems related to the resin encapsulation process arise. In the resin encapsulation process, it is necessary to prevent the resin from flowing into through hole (120), because the side (conductor (120)) of the IC package (100) is to be used as an I/O terminal. When resin encapsulation is performed by potting, a supply of too much resin may cause the resin to leak into the through hole. Thus, the need arises to control the dispense of resin for individual ICs with particular accuracy, resulting in increased burdens on production management, thereby adversely affecting IC package throughput.

Furthermore, the external shape of the resin encapsulation based on potting is not planar. Thus, in testing and mounting processes subsequent to the separation into individual IC packages, handling, such as pickup by suction, becomes difficult, thereby adversely affecting throughput.

On the other hand, when resin encapsulation is performed by molding process, custom metal molds must be provided depending on the type and size of IC packages in order to resin-encapsulate IC packages individually. Thus, facility utilization efficiency is deteriorated, increasing the initial cost and thus adversely affecting throughput.

It is an objective of the present invention to solve at least one of the afore-described problems and to provide an IC package for improving throughput and a fabrication method therefore.

### SUMMARY OF THE INVENTION

According to the present invention, an IC package and fabrication method therefore is provided. An exposed I/O terminal is disposed on a side of this IC package. The IC package includes an IC chip mounting substrate, an IC chip mounted on the IC chip mounting substrate, and an encapsulating member for encapsulating the IC chip. On a side of the chip mounting substrate is formed a trench for exposing a conductor that forms at least a portion of the I/O terminal, and one end of the trench is closed by a cap member, and the encapsulating member covers the IC chip and cap member. A ceramic material may be used as a material for the chip mounting substrate and cap member. The chip mounting substrate may also be comprised of a printed wiring substrate, and the cap member may be formed by a solder resist film.

Furthermore, an IC package fabrication method according to the present invention comprises the steps of: providing a chip mounting substrate having a through hole formed therein and a predetermined electrical wiring; closing one end of the through hole by use of a cap member; mounting a plurality of IC chips on the chip mounting substrate; encapsulating by a molding resin areas over the chip mounting substrate including the plurality of IC chips; and separating it into individual IC packages.

### BRIEF DESCRIPTION OF THE DRAWINGS

FIG. 1 shows a cross-sectional view of an IC package according to a prior art.

FIG. 2 shows various fabrication steps for an IC package according to a first embodiment of the present invention.

FIG. 3 shows various fabrication steps for an IC package according to a second embodiment of the present invention.

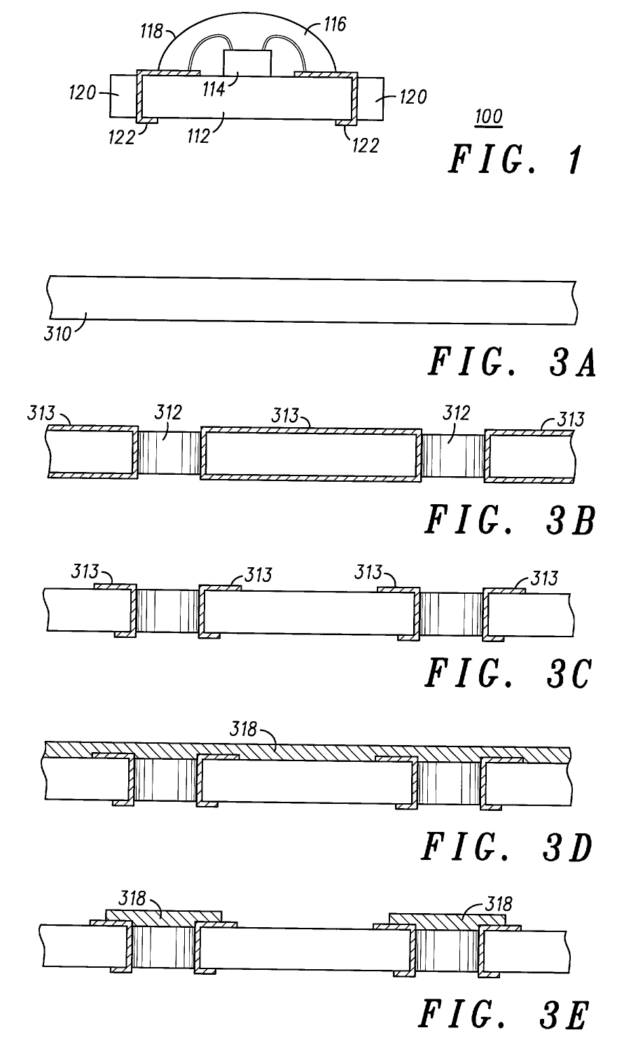

### DETAILED DESCRIPTION OF THE PREFERRED EMBODIMENTS

Although some embodiments of the present invention are described below, it should be noted that the present invention is not limited thereto.

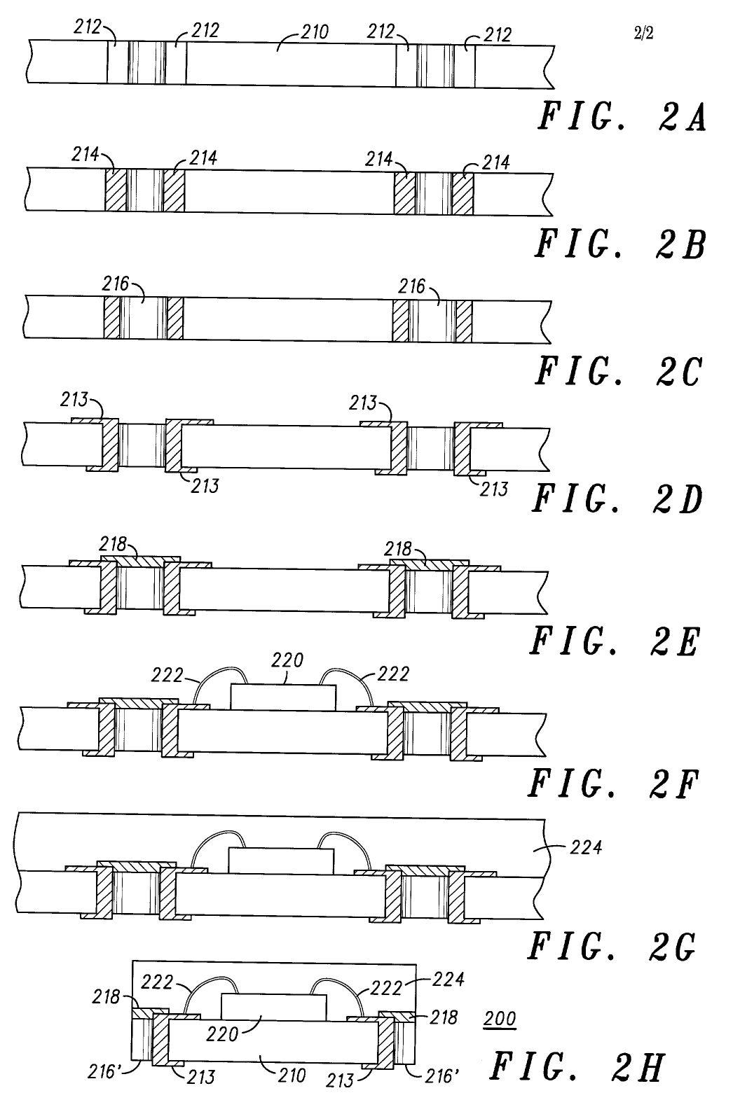

FIG. 2 shows various fabrication steps, in sequence, for fabricating an IC package according to a first embodiment of the present invention. First, an IC chip mounting substrate, or interposer substrate (210), is provided. As described above, the “interposer substrate” is an insulating member located between an I/O terminal and IC chip of an IC package, and serves to define locations of I/O terminals. The interposer substrate (210) in the present embodiment is made of a ceramic material and has a thickness of about 0.2 to 0.3 mm.

In the step shown in FIG. 2A, a plurality of first through holes (212) are formed in predetermined locations of the interposer substrate (210). The predetermined locations substantially correspond to an outer periphery of the IC package. The first through hole (212) may be formed by use of a drill or punched by use of a mold (press work). From the standpoint of cost reduction, holes are preferably formed by use of press work.

In the step shown in FIG. 2B, the first through hole (212) drilled in the preceding step is filled with a conductive material (214).

In the step shown in FIG. 2C, a second through hole (216) is drilled so that a portion of the conductive material (214) filled in the first through hole (212) is removed. This second hole (216) is also formed by use of a drill or dies in a similar manner to the first through hole (212). It should be noted, however, that the diameter of the second through hole (216) is larger than that of the first through hole (212). The diameters of the first and second through holes (212 and 216) are about 0.2 to 0.3 mm. The end face of the conductive material (214) with its portion removed by the second through hole (216) assumes a domed concave shape, which has a larger surface area than when it is planar, and thus the surface area of an I/O terminal described hereinbelow also becomes larger.

In the step shown in FIG. 2D, predetermined electrical wirings are printed on front and back surfaces of the interposer substrate (210) by using metal powder, such as molybdenum (Mo) and tungsten (Tw). The predetermined electrical wiring (213) includes wiring pattern on the front surface of the interposer substrate and wiring pattern for an I/O pad on the back surface thereof. The electrical wirings printed on the front and back surfaces of the interposer substrate (210) are electrically interconnected via the conductive material (214).

In the step shown in FIG. 2E, a cap member (218) made of ceramic material is used to cover the second through hole (216). In the present embodiment, the cap member has a width greater than 0.2 to 0.3 mm, which is larger than the diameter of the second through hole, and a thickness of 0.08 to 0.1 mm. The shape and size of the cap member (218) are not limited to those in the present embodiment, but it may have a width, length, and thickness such that one end of a one or more second through holes (216) is closed. Next, the interposer substrate (210) and cap member (218) are baked, and the printed electrical wirings are gold-plated. As the material for the cap member (218), a solder resist film or the like may be used, as well as ceramic material similar to the interposer substrate (210). However, if the ceramic material is used as in the present embodiment, a hole structure with its one end closed may be formed simultaneously in the baking process of the interposer substrate (210). Therefore, from the standpoint of reducing fabrication steps, the cap member (218) is preferably made of a ceramic material.

In the step shown in FIG. 2F, an IC chip (220) is mounted in a predetermined location on the interposer substrate (210). The IC chip (220) is electrically connected to the electrical wirings on the interposer substrate (210) and the conductive material (214) via wires (222).

In the step shown in FIG. 2G, areas over the interposer substrate (10), including a plurality of IC chips (220), are entirely encapsulated by an encapsulating resin (224). At this step, the cap member (218) formed in the step of FIG. 2E prevents the resin from being buried into the second through hole. This encapsulation process is performed not by potting but by metal molding. This eliminates the need for controlling the dispense of the encapsulating resin with high accuracy, thus reducing the burden on production management. The dies used in this step may be used commonly for the IC package, independently of the type and size of the IC package. Conventionally, it was necessary to mold with appropriate dies which matches to individual IC packages due to prevent resin leakage from the through hole. However, in the present embodiment, because a plurality of IC packages may be molded together, the need for providing dies for individual IC packages is eliminated, so that the dies may be used commonly for IC packages of this type, thereby enhancing facility utilization efficiency.

FIG. 2H shows the state after each IC package (200) is separated. This separation is achieved at the second through hole (216) by, for example, dicing or breaking. As shown, the IC package (200) that is eventually formed has an I/O terminal (214) exposed on a side thereof. That is, a trench (216′) that exposes the conductor (214) that forms a part of I/O terminal (213, 214) is formed on a side of the interposer substrate (210), and this trench (216′) corresponds to a portion (half) of the second through hole (216) to form a half-through hole, which serves as an I/O terminal attachment portion. It should be note that in the present embodiment, each IC package is cut (separated) to form a half through hole, although it is not limited to cut at this position. In theory, it may be cut at any location outside the I/O terminal (213). It is preferable to cut along the end face of the I/O terminal from the standpoint of further miniaturization, whereas it is preferable, from the viewpoint of improved manufacturing process efficiency with reduced cutting steps, to cut it so that a half through hole is formed as described above.

FIG. 3 shows fabrication steps, in sequence, for fabricating an IC package according to a second embodiment of the present invention.

In the step of FIG. 3A, an IC chip mounting substrate, or interposer substrate (310), is provided. In the present embodiment, the interposer substrate (310) is comprised of a printed circuit board (PCB) where a copper foil is coated on the surface thereof. It is preferable to use the PCB from the standpoint of reducing a difference in coefficient of linear expansion between the interposer substrate (310) and encapsulating resin (224).

In the step of FIG. 3B, through holes (312) are formed in predetermined locations on the interposer substrate (310), and the entire interposer substrate (310) is treated by copper plating. Subsequently, predetermined patterns (313) for electrical wirings are formed on front and back surfaces of the interposer substrate (310). This pattern formation process is performed using existing techniques, such as resist coating, masking, exposure, and resist removal. Then, gold plating is applied to the electrical wirings formed.

FIG. 3C shows the state of the interposer substrate (310) with predetermined electrical wirings (313) applied.

In the step of FIG. 3D, the interposer substrate (310) is entirely coated by a solder resist film (318). This solder resist film (318) serves as a cap member. The cap member (218) made of a ceramic material applied in the step of FIG. 2E has a predefined form and is aligned so as to cover the vicinity of the second through hole (216), rather than entirely covering the interposer substrate. In the present embodiment, however, the interposer substrate (310) is entirely covered, eliminating the need for such alignment. It should be appreciated that a predetermined shape of the solder resist film (318) may be initially placed with a predetermined geometry over the through hole (312), although it is desirable from the standpoint of the fabrication step count to perform the process as in the present embodiment.

In the step of FIG. 3E, the solder resist film is removed so as to leave the solder resist film (318) near the through hole (312). In this way, a cap member (318) is formed that closes one end of the through hole (312). An IC package is then completed through process steps similar to FIGS. 2F through 2H.

With the IC package (200) and its fabrication method according to the present embodiment, one end of the trench (216′) is closed by the cap member (218, 318), which is covered by the overlying encapsulating resin (224), so that the end face of the cap member (218, 318) and encapsulating resin (214) forms an outermost side of the IC package (200). Conventionally, encapsulation could not be applied over the trench (216′) without sacrificing the I/O terminal located on the side of the IC package; in the present embodiment, however, such encapsulation can be achieved. This means that because an area that can be encapsulated over the interposer substrate (210, 310) is increased as compared to the prior art, a larger IC chip can be mounted thereon. Thus, in addition to miniaturization, enhanced functionality and improved performance can be attained. The top surface of the cap member (218, 318) is covered by the encapsulating resin (224), and there exists space surrounded by the bottom surface of the cap member (218, 318) and the trench (216′) to thereby expose the conductor (214) on the side of the IC package, which may be used as an I/O terminal. Additionally, because the encapsulating resin (224) is formed by use of a molding die, it is easy to planarize the external shape of the encapsulating resin (224) (top surface of the IC package (200)). In the present embodiment, a substantially rectangular parallelepiped shape is implemented. This facilitates handling, such as pickup by suction, in subsequent inspection and mounting processes.

As described above, the IC package and its fabrication method according to the present embodiment allows for improved IC package throughput through reduced burdens on production management, improved facility utilization efficiency, and so forth.

What is claimed is:

1. An IC package having at least a conductive I/O terminal (213) exposed around the IC package (200), the IC package comprising:
a chip mounting substrate (210), where a terminal attachment portion (216′) for attaching the I/O terminal (213) is formed around the chip mounting substrate (210);
an IC chip (220) mounted on the IC chip mounting substrate (210) and electrically coupled to the I/O terminal (213);
a cap member (218) for covering the terminal attachment portion (216′) and a portion of the I/O terminal; and
an encapsulating member (224) for covering the IC chip (220) and the cap member (218).

2. The IC package according to claim 1, wherein the chip mounting substrate and the cap member are made of a ceramic material.

3. The IC package according to claim 1, wherein the chip mounting substrate is comprised of a printed wiring board and the cap member is comprised of a solder resist film.

4. The IC package according to claim 1, wherein the external shape of the encapsulating member is a rectangular parallelepiped.

5. A method for fabricating an IC package (200), the method comprising the steps of:
providing a chip mounting substrate (210, 310) having predetermined electrical wirings (213, 313) and through holes (216, 312) being formed at predetermined locations;
closing one end of at least one of the through holes (216, 312) by using a cap member (218, 318);
mounting a plurality of IC chips (220) on the chip mounting substrate (210, 310);
connecting each of the IC chips (220) to the electrical wirings (213, 313);
encapsulating areas over the chip mounting substrate (210, 310) including the plurality of IC chips (220) by resin molding (224); and
separating the chip mounting substrate (210, 310) into individual IC packages (200) each of which has an IC chip mounted thereon.

6. A method for fabricating an IC package (200) according to the claim 5, wherein the step of providing a chip mounting substrate includes forming through holes (312) at predetermined locations of a printed wiring board (310); copper-plating the printed wiring board (310) with through holes formed therein; and forming a predetermined electrical wiring (313) on the printed wiring board (310), and wherein the cap member is a solder resist film (318).

7. A method for fabricating an IC package (200), the method comprising the steps of:
forming a plurality of first through holes (212) at predetermined locations of a chip mounting substrate (210) made of a ceramic material;
filling conductive material (214) into the plurality of first through holes (212);
forming at least a second through hole (216) so as to remove a portion of the conductive material (214) filled into the first through hole (212);
printing a predetermined electrical wiring (213) over the chip mounting substrate (210);
closing one end of at least one of the second through hole (216) by using a cap member (218) made of a ceramic material;
baking the chip mounting substrate (210) and the cap member (218);
mounting a plurality of IC chips (220) on the chip mounting substrate (210);
connecting each of the IC chips (220) to the electrical wiring (213);
encapsulating areas over the chip mounting substrate (210) including the plurality of IC chips (220) by using resin molding (224); and
separating the chip mounting substrate (210) including the plurality of IC chips (220) into individual IC packages (200).
